(19) United States
(12) Patent Application Publication
(10) Pub. No.: US 2026/0171795 A1
(43) Pub. Date: Jun. 18, 2026

(54) SYSTEM AND METHOD OF UTILIZING DC-DC CONVERTERS TO IMPROVE POWER DENSITY AND IMPROVE BATTERY UTILIZATION

(71) Applicant: Fluence Energy, LLC, Arlington, VA (US)

(72) Inventors: Niloy Sarkar, Jalpaiguri, West Bengal (IN); Wells Case Jacobson, Jr., Arlington, VA (US)

(73) Assignee: Fluence Energy, LLC, Arlington, VA (US)

(21) Appl. No.: 18/852,105

(22) PCT Filed: Sep. 6, 2024
(86) PCT No.: PCT/US2024/045574

§ 371 Date: Sep. 27, 2024

Related U.S. Application Data
(60) Provisional application No. 63/541,140, filed on Sep. 28, 2023.

(51) Int. Cl. H02J 1/102

(52) U.S. Cl. CPC H02J 1/102

(57) ABSTRACT

An energy storage system includes a plurality of energy storage nodes, each of which includes a battery storage element, a plurality of DC-DC converters connected in parallel, each of which is connected to a corresponding one of the energy storage nodes, and a controller coupled to the plurality of DC-DC converters and configured to execute a power balancing protocol. The power balancing protocol includes collecting and recording electrical data from each of the DC-DC converters, calculating an average power output for the DC-DC converters based on the electrical data, calculating a required change in a no-load voltage value for each of the DC-DC converters, and updating the no-load voltage value for each of the DC-DC converters based on the calculated required change in the no-load voltage value for each of the DC-DC converters. A method for executing a power balancing protocol is also provided.

### CROSS-REFERENCE TO RELATED APPLICATIONS

This application is a U.S. National Phase Application of International Application No. PCT/US2024/045574, filed on Sep. 6, 2024, titled “System and Method of Utilizing DC-DC Converters to Improve Power Density and Improve Battery Utilization,” the entirety of which is incorporated by reference herein. International Application No. PCT/US2024/045574 claims priority to U.S. Provisional Patent Application No. 63/541,140, filed on Sep. 28, 2023, titled “System and Method of Utilizing DC-DC Converters to Improve Power Density and Improve Battery Utilization,” the entirety of which is incorporated by reference herein.

### TECHNICAL FIELD

The present subject matter relates to energy storage systems and embedded methods, and more particularly to an energy storage system that includes parallelized DC-DC converters to improve energy density, as well as to methods for managing the parallelized DC-DC converters.

### BACKGROUND

Battery energy storage systems, compound energy storage systems, as well as energy provisioning systems, generally are required to provide electrical energy as efficiently as possible. Many of these systems utilize a DC-DC converter between the energy provisioning device (e.g., generator, solar panel, or battery) and a load or grid. The DC-DC converter regulates and smooths out or amortizes the DC voltage provided by the energy provisioning device such that the load receives a consistent voltage over time. DC-DC converters also provide other benefits to the energy storage system, such as galvanic isolation and noise reduction.

The voltage from the DC-DC converter is direct current, and in many cases will ultimately need to be converted to alternating current. To perform that conversion, a power conversion system (PCS) converts the provided direct current into alternating current. The PCS benefits from a well-regulated direct current, as irregularities in the direct current will impede the operation of the PCS and will ultimately reduce the overall alternating current output of the energy storage system.

However, a single DC-DC converter performs voltage regulation at a given scale or level of granularity, potentially being unable to make minor adjustments, or becoming overwhelmed by major voltage shifts. Additionally, control of the DC-DC converter is likewise only as granular and robust as the DC-DC converter itself.

Hence, there is a need for systems and methods directed to improving the ability of DC-DC converters in an energy storage system to tightly regulate voltage, in order to allow for higher energy density, as well as improve battery utilization and downtime.

### SUMMARY

In a first example, an energy storage system 101 includes a plurality of energy storage nodes 105A-N, each of which includes a battery storage element 106A-N, a plurality of DC-DC converters 109A-N connected in parallel, each of which is connected to a corresponding one of the energy storage nodes 105A-N, and a controller 113 coupled to the plurality of DC-DC converters 109A-N and configured to execute a power balancing protocol. The power balancing protocol includes collecting and recording electrical data 111A-N from each of the plurality of DC-DC converters 109A-N, calculating an average power output for the plurality of DC-DC converters 109A-N based on the electrical data 111A-N, calculating a required change in a no-load voltage value for each of the plurality of DC-DC converters 109A-N, and updating the no-load voltage value for each of the plurality of DC-DC converters 109A-N based on the calculated required change in the no-load voltage value for each of the plurality of DC-DC converters 109A-N.

In a second example, a method includes connecting a plurality of parallel DC-DC converters 109A-N to a plurality of energy storage nodes 105A-N; collecting and recording electrical data 111A-N from each of the plurality of parallel DC-DC converters 109A-N; calculating an average power output for the plurality of parallel DC-DC converters 109A-N based on the electrical data 111A-N; calculating a required change in a no-load voltage value for each of the plurality of parallel DC-DC converters 109A-N; and updating the no-load voltage value for each of the plurality of parallel DC-DC converters 109A-N based on the calculated required change in the no-load voltage value for each of the plurality of parallel DC-DC converters 109A-N.

Additional objects, advantages and novel features of the examples will be set forth in part in the description which follows, and in part will become apparent to those skilled in the art upon examination of the following and the accompanying drawings or may be learned by production or operation of the examples. The objects and advantages of the present subject matter may be realized and attained by means of the methodologies, instrumentalities and combinations particularly pointed out in the appended claims.

### BRIEF DESCRIPTION OF THE DRAWINGS

The drawing figures depict one or more implementations in accordance with the present concepts, by way of example only, not by way of limitations. In the figures, like reference numerals refer to the same or similar elements.

FIG. 1A depicts a system that includes an energy storage system, an energy system, and an electrical application.

FIG. 1B illustrates a first energy storage node of a plurality of energy storage nodes of the energy storage system of FIG. 1A coupled to the electrical application.

FIG. 2 illustrates a first energy storage node of a plurality of energy storage nodes of the energy storage system of FIG. 1A coupled to the electrical application.

FIG. 3 is a high-level functional block diagram of the energy storage system of FIG. 1A that depicts components of the control system and the energy storage nodes to control a plurality of DC-DC converters connected in parallel.

FIG. 4 is a cutaway view of the first energy storage node of the plurality of energy storage nodes and shows details of a plurality of battery storage elements.

FIG. 5 is a flowchart of the converter power balancing protocol.

FIG. 6 is a graph of a voltage versus current droop curve.

### PARTS LISTING

100 System
101 Energy Storage System
102 Energy System
103 Electrical Application
104 Power Conversion System
105A-N Energy Storage Nodes
106, 106A-N Battery Storage Elements
107 Power Conversion Subsystem
108 Transformer
109A-N DC-DC Converters
110 Control Subsystem
111A-N Electrical Data
112 No-load Voltage Value
112A-N No-load Voltage Values
113 Controller
114A-N Distributed Power Conversion Systems
115 Control System
116 Energy Source
119A-N Distributed DC-DC Converters
120 Physical Space
121A-N Data Collection Sensors
125 Power Bus
155A-N Battery Cores
205 Power Inverter
210 Rectifier
215 DC-DC Converter
305, 305A-N Network
311, 351 Network Communication Interface
312, 352 Processor
313, 353 Memory
315A-N Sensors
330A-B Power Balancing Control Programming
370A-N Environmental Sensors
400 Enclosure
500 Method

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, transfer functions, and/or circuitry have been described at a relatively high-level, without detail, in order to avoid unnecessarily obscuring aspects of the present teachings.

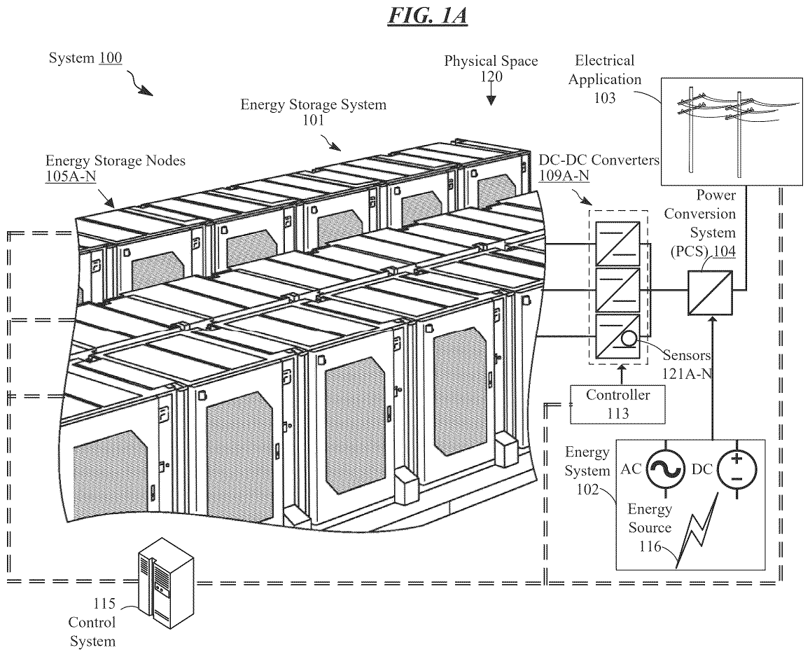

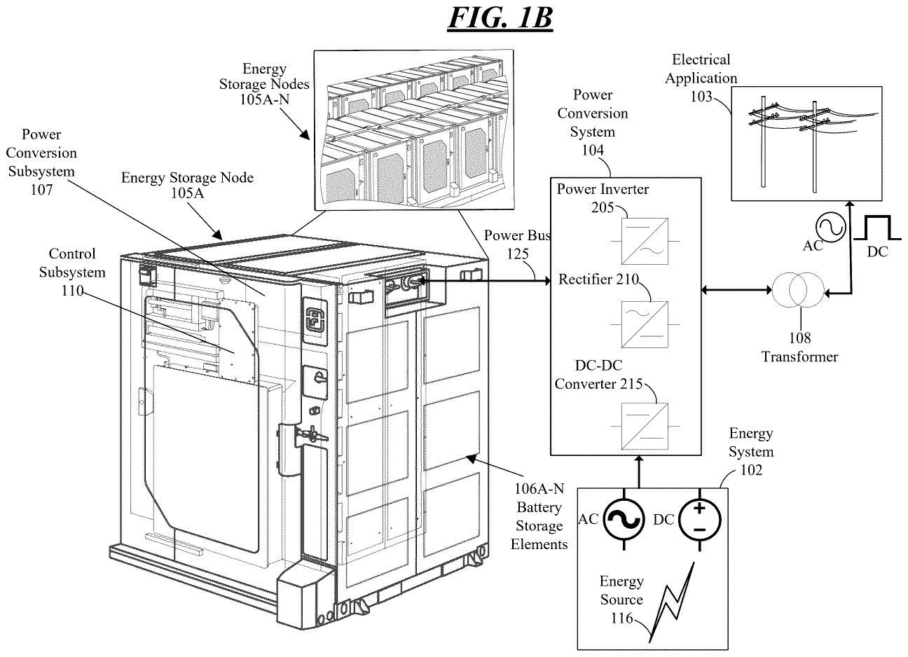

Unless otherwise indicated, any embodiment can be combined with any other embodiment. In particular, FIGS. 1A-6 and the associated text are all combinable with each other.

The term “coupled” as used herein refers to any logical, physical, electrical, or optical connection, link or the like by which signals or light produced or supplied by one system element are imparted to another coupled element. Unless described otherwise, coupled elements or devices are not necessarily directly connected to one another and may be separated by intermediate components, elements, or communication media that may modify, manipulate, or carry the light or signals.

The orientations of the system 100, energy storage system 101, energy storage nodes 105A-N, associated components, and/or any complete devices, incorporating battery storage elements 106A-N, such as batteries, such as shown in any of the drawings, are given by way of example only, for illustration and discussion purposes. In operation for a particular energy storage application, an energy storage node 105A-N may be oriented in any other direction suitable to the particular application of the energy storage system 101, for example upright, sideways, or any other orientation. Also, to the extent used herein, any directional term, such as left, right, front, rear, back, end, up, down, upper, lower, top, bottom, and side, are used by way of example only, and are not limiting as to direction or orientation of any energy storage system 101 or energy storage nodes 105A-N; or component of an energy storage system 101 or energy storage nodes 105A-N constructed as otherwise described herein.

Unless otherwise indicated, any multiplicity of components, such as energy storage nodes 105A-N or battery storage elements 106A-N can include any number of said components, including as few as one, and are not limited by the depicted number of components. Unless otherwise indicated, any coupled electrical components can be linked in series or in parallel. In the case of energy storage nodes 105A-N or battery storage elements 106A-N, the components may be linked in series, in parallel, or a combination thereof depending upon a state of a switch or a submodule.

The energy storage DC-DC converter parallelization and management technologies disclosed herein utilize multiple DC-DC converters connected in parallel, thereby providing more nuanced and granular control over voltage passing through the DC-DC converter, resulting in tighter voltage regulation allowing for higher voltage PCS systems, which in turn allow for higher energy density and improve battery utilization and downtime.

Additionally, the parallelized DC-DC converters, in order to affect their tight voltage regulation, are managed by a power balancing protocol, utilizing the droop curve of each DC-DC converter to optimize the real-time, responsive voltage adjustments performed by the DC-DC converters.

Reference now is made in detail to the examples illustrated in the accompanying drawings and discussed below.

FIG. 1A depicts a system 100 that includes an energy storage system 101, energy system 102, and an electrical application 103. For example, the energy storage system 101 can be a battery energy storage system (BESS). The energy storage system 101 is coupled to the energy system 102 and the electrical application 103. Energy storage system 101 can include a power conversion system 104, a plurality of energy storage nodes 105A-N, an optional transformer 108 (FIG. 1B), and a control system 115. Components of the energy storage system 101 can be located at a physical space 120 that is outdoors or indoors, for example, inside of a building, a container, or other structure.

Energy system 102 can include any suitable system for producing electrical energy from an energy source 116. Energy system 102 can be a renewable energy system in which the energy source 116 can be replenished. Such a renewable energy source 116 can include solar power, wind power, geothermal power, biomass, and hydroelectric power. For example, the renewable energy system 102 can be implemented as an array of photovoltaic modules. The photovoltaic (PV) modules can include crystalline silicon, amorphous silicon, copper indium gallium selenide (CIGS) thin film, cadmium telluride (CdTe) thin film, and concentrating photovoltaic which uses lenses and curved mirrors to focus sunlight onto small, but highly efficient, multi-junction solar cells. In another example, the energy system 102 can include wind turbines or gas turbines. In some examples, the energy system 102 can be a non-renewable energy system in which the energy source 116 includes a non-renewable energy source, such as a fossil fuel.

Electrical application 103 can include an electrical grid, such as a power grid, or a smaller local load, such as a backup power system, for a facility such as a hospital, manufacturing site, residential home, or other suitable facility. The electrical application 103 may deliver AC or DC power for on-grid or off-grid applications, including commercial, industrial, or residential applications. The electrical application 103 may deliver power to buildings, electric vehicle charging stations, etc., including a variety of electrical loads that consume AC or DC electric power. The electrical application 103 can be a front-of-the-meter system that is owned or operated by a utility company or a behind-the-meter system that directly supplies buildings and homes with electricity.

Energy source 116 can be a renewable energy source, such as solar power and wind power, which can be intermittent and less reliable compared to fossil fuels. To improve resiliency, energy storage system 101 can store energy from the energy system 102 when the production from the energy source 116 is high. Later on, the energy storage system 101 can dispatch the energy to the electrical application 103 when demand is high or production from the energy source 116 is not keeping up with demand. Moreover, events may occur when a connected load or an operating demand load of the electrical application 103 is excessive or there is electrical grid instability, such as during extreme weather. By storing energy from the energy source 116 and then dispatching the energy during such events, the energy storage system 101 can continue to dispatch a required power flow of the electrical application 103. The energy storage nodes 105A-N can also be charged via the electrical application 103.

Energy storage nodes 105A-N include battery storage elements 106A-N. The battery storage elements 106A-N can be: (1) a single battery cell; (2) a cell grouping, including several battery cells in parallel configuration; (3) a battery submodule or module, including several battery cells in parallel and serial configuration; (4) a battery string, including several battery modules in series; (5) a battery bank, including several battery strings in parallel; (6) other known energy storage elements; and/or (7) a combination thereof. For example, the battery storage elements 106A-N can include a plurality of batteries of any existing or future reusable battery technology that can be used in a battery energy storage system (BESS), including, but not limited to, lithium ion or flow batteries, or mechanical storage, such as flywheel energy storage, compressed air energy storage, pumped-storage hydroelectricity, gravitational potential energy, or a hydraulic accumulator, for example.

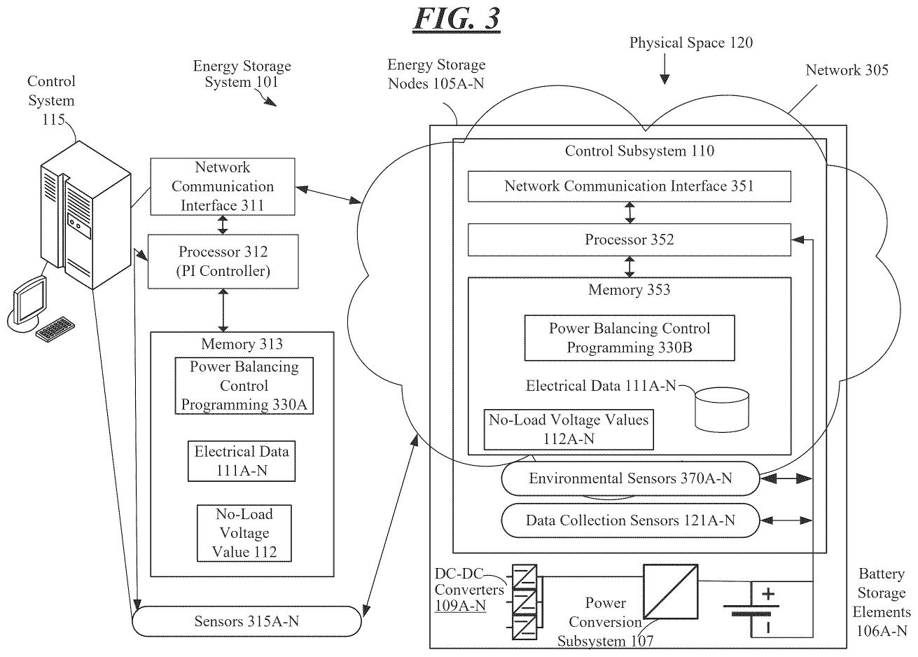

FIG. 1B illustrates a first energy storage node 105A of the plurality of energy storage nodes 105A-N of FIG. 1A coupled to the electrical application 103. Energy storage nodes 105A-N can include a battery storage element 106, a power conversion subsystem 107, and a control subsystem 110, the power conversion subsystem 107, or a combination thereof. Energy storage system 101 can be controlled such that the electrical application 103 is fulfilled while distributing the dispatch of required power flow across the plurality of battery storage elements 106A-N based on electrical data 111A-N (FIG. 3) related to the DC-DC converters 109A-N of the energy storage nodes 105A-N.

Power conversion system 104 can include a power inverter 205, a rectifier 210, a DC-DC converter 215, other power conversion elements, or a combination thereof. Power inverter 205 can be configured to convert a DC source, such as from the battery storage elements 106A-N, into an AC waveform. Rectifier 210 can be configured to convert an AC source, such as from the energy system 102 or electrical application 103, into DC for the battery storage elements 106A-N. DC-DC converter 215 can be configured to convert a DC source, such as from the battery storage elements 106A-N, into a different DC source characteristic.

If the energy source 116 is wind power, then the power conversion system 104 can convert the AC electricity produced into DC power for storage in the plurality of energy storage nodes 105A-N via the rectifier 210. If the energy source 116 is solar power, then the power conversion system 104 can convert the DC electricity into a different voltage level via the DC-DC converter 215. The power inverter 205 can convert the required power flow from the energy storage system 101 from DC power into AC power during dispatch to the electrical application 103. For example, the power inverter 205 can be configured to convert power on a power bus 125 for use by the electrical application 103. For example, the power inverter 205 converts DC power stored in the energy storage nodes 105A-N into AC power for consumption by electrical loads of the electrical application 103.

The power conversion system 104 is coupled to the energy system 102 and the electrical application 103 to provide a required power flow to the electrical application 103 by discharging the plurality of energy storage nodes 105A-N or the required power flow from the energy system 102 for charging the plurality of energy storage nodes 105A-N. The power conversion system 104 can be coupled to an optional transformer 108 (FIG. 1B). The optional transformer can step up or step down the required power flow to and from the electrical application 103, such as an AC voltage.

When the energy storage nodes 105A-N provide direct current, the power conversion system 104 transforms direct current into alternating current for use by the electrical application 103 and normalizes the amperage from the battery modules 105A-N to the electrical application 103. Additionally, when the energy storage nodes 105A-N require direct current, the central power conversion system 104 transforms alternating current from the electrical application 103 into direct current and normalizes the amperage from the electrical application 103 to the energy storage nodes 105A-N.

Power conversion subsystem 107 includes similar hardware and software as the more centralized power conversion system 104. Power conversion subsystem 107 is distributed more locally to each of energy storage nodes 105A-N. The control subsystem 110 can be configured for local computation, processing, and control of the battery storage elements 106A-N and the power conversion subsystem 107. The control system 115 can be configured for more centralized computation, processing, and controls of the overall energy storage system 101, energy system 102, electrical application 103, and power conversion system 104. Both the control subsystem 110 and control system 115 can include a single board computer, an application-specific integrated circuit (ASIC), microcontroller, digital signal processor (DSP), field-programmable gate array (FPGA), or a combination thereof.

Turning back to FIG. 1A, to facilitate providing and receiving direct current, the energy storage nodes 105A-N can be coupled to the power conversion system 104. The power conversion system 104 is configured to standardize power inputs and outputs to and from the energy storage nodes 105A-N.

Between the PCS 104 and the energy storage nodes 110A-N, an array of DC-DC converters 109A-N are installed in parallel. Using multiple DC-DC converters 109A-N connected in parallel at the energy storage node 110A-N side of the PCS 104 and running in parallel creates a DC bus at the PCS 104 DC input. The created DC bus of DC-DC converters 109A-N can have tight voltage regulation, preferably in the range of 1400-1500 volts DC. The tight voltage regulation range will enable the PCS 104 to operate at high AC voltage, for example 850 volts AC, resulting in the PCS 104 producing higher power over conventional PCS implementations and thus improve the power density of the BESS 100. The DC-DC converters 109A-N are not necessarily connected in parallel on the energy storage node 110A-N side, and preferably each energy storage node 110A-N will have its own respective DC-DC converter 109A-N.

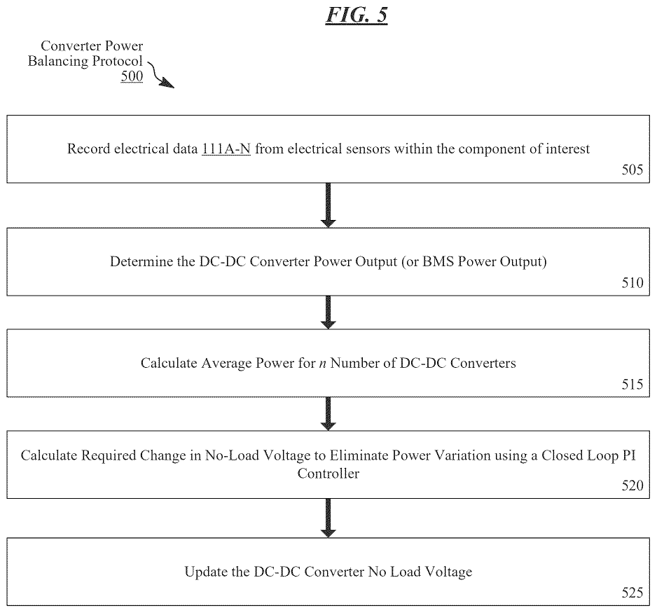

DC-DC converters 109A-N can also be operated in voltage (V) versus current (I) droop control. Utilizing droop control, DC-DC converters 109A-N can share power equally without any active communication. However, in practice due to differences in sensor accuracy and varying impedances in the cabling connected between the PCS 104 and the DC-DC converters 109A-N, there will be a difference in power sharing. Though this difference in power sharing may not be immediately significant, but nevertheless during long-term operation this difference can lead to significant difference in state of charge (SOC) which can lead to underutilization of the energy capacity of the energy storage nodes 110A-N. The converter power balancing protocol 500 described in FIG. 5 works to resolve these differences in power sharing.

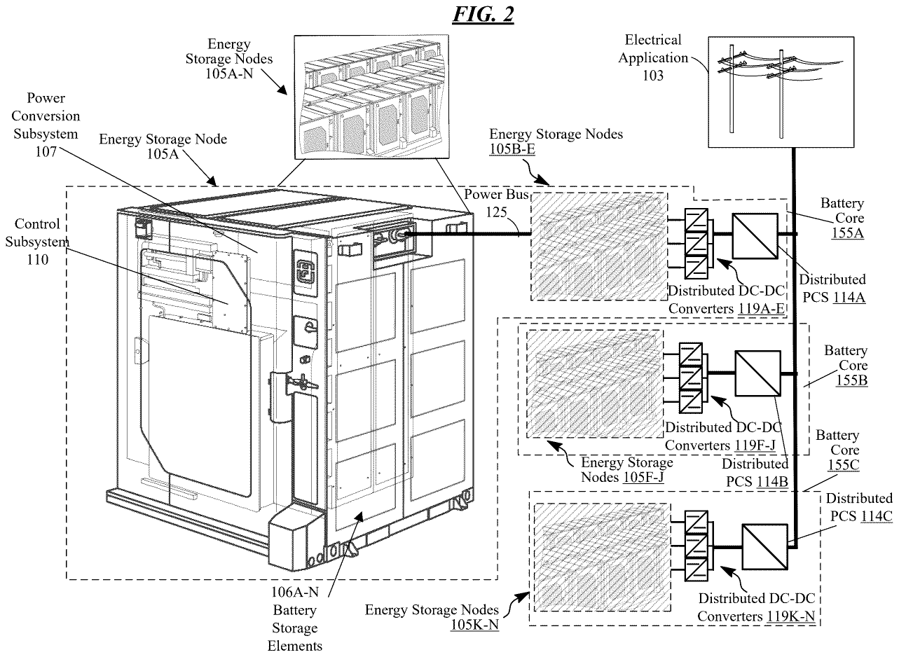

FIG. 2 illustrates a first energy storage node 105A of a plurality of energy storage nodes 105A-N of the energy storage system 101 of FIG. 1A coupled to the electrical application 103. The energy storage nodes 105A-N are organized into collections of nodes 105B-E, 105F-J, 105K-N, each collection paired with a distributed power conversion system 114A-C. A grouping of nodes 105A-E with a distributed power conversion system 114A constitutes a battery core 155A.

The distributed power conversion system 114A-C can include: (1) an inverter, converting the DC source of the battery storage element 106A-N to an AC waveform, and vice versa; (2) a DC/DC converter, converting the DC source of the energy storage element 210 to a different DC source characteristic; (3) other known power conversion elements; or (4) a combination thereof. The distributed power conversion systems 114A-C can service an individual energy storage node 105A, or any number of energy storage nodes 105A-N. Multiple energy storage nodes 105A-N are generally arranged in series, although other wiring sequences are contemplated. A distributed power conversion system 114A servicing multiple energy storage nodes 105A-E can be a battery core 255A, and can be controlled by the controller 113 (see FIG. 1A). The controller 113 can coordinate with a node controller present in each associated energy storage node 105A-E. The controller 113 can be part of the control system 115. Alternatively, the controller 113 can be a separate controller.

Arrays of distributed DC-DC converters 119A-E, 119F J, 119K-N are installed in parallel between the distributed power conversion systems 114A-C and their respective energy storage nodes 105B-E, 105F-J, 105K-N. The distributed DC-DC converters 119A-E, 119F-J, 119K-N in FIG. 2 service their respective distributed PCSs 114A-C in the same manner that the DC-DC converters 109A-N service the PCS 104 in FIG. 1A.

Physical data collection sensors and data logging can be used throughout the energy storage system 100, to collect operational and environmental data, in particular power output of the DC-DC converters 109A-N, 119A-N to produce electrical data 111A-N (see FIGS. 3 and 5), such as voltage, current, and power, for example. For example, data collection sensors 121A-N, such as current sensors and voltage sensors, can be arranged inside the DC-DC converters 109A-N, 119A-N. Alternatively, or additionally, data collection sensors 121A-N, such as current sensors and voltage sensors, can be arranged or on both sides (inputs and outputs between DC-DC converters 109A-N, 119A-N and energy storage nodes 105A-N, and between DC-DC converters 109A-N, 119A-N and electrical application 103, respectively) of the DC-DC converters 109A-N, 119A-N.

Physical data collection sensors and data logging can be used throughout the energy storage system 100, to collect operational and environmental data, in particular voltage, current, temperature, or state of charge from the components of the battery energy storage system, such as the power input and output of PCSs or BMSs, to produce electrical data 111A-N (see FIGS. 3 and 5).

Physical data collection sensors and data logging can be used throughout energy storage node 105A, to collect operational and environmental data, in particular voltage, current, temperature, or state of charge from the components of the energy storage node 105A, to produce electrical data 111A-N (see FIGS. 3 and 5).

FIG. 3 is a high-level functional block diagram of the energy storage system 101 of FIG. 1A that depicts components of the control system 115 and the energy storage nodes 105A-N to control a plurality of DC-DC converters 109A-N connected in parallel based on operational data or electrical data 111A-N (e.g., current, voltage, power) collected from each of the plurality of DC-DC converters 109A-N and/or environmental data, in particular voltage, current, temperature, or state of charge from the components of the battery energy storage system, such as the power input and output of PCSs or BMSs. The electrical data 111A-N can also include at least one of current and voltage or power output of the power conversion system 104. As shown, the plurality of energy storage nodes 105A-N include a battery storage element 106A-N, a plurality of DC-DC converters 109A-N connected in parallel, a power conversion subsystem 107, and a control subsystem 110 to receive electrical data 111A-N from the plurality of DC-DC converters 109A-N, the power conversion subsystem 107, or a combination thereof.

The control system 115, energy storage nodes 105A-N, electrical application 103, and other components of the system 100 can be in communication over a network 305 or one or more networks 305A-N. The networks 305A-N can be a local area network 305A, wide area network 305B, or a combination thereof. For example, the control system 115 can be coupled via a local area network 305A to the energy storage nodes 105A-N and the electrical application 103. Alternative or additionally, the control system 115 can be coupled via a wide area network 305B to the energy storage nodes 105A-N and electrical application 103. Or the control system 115 can be coupled via a combination of networks 305A-N, such as via a local area network 305A to components of the energy storage system 101, including the energy storage nodes 105A-N, and coupled via a wide area network 305B to the electrical application 103.

Control system 115 includes a network communication interface 311 configured for wired or wireless communication over the network 305. The control system 115 further includes a memory 313, and a processor 312 coupled to the network communication interface 311 and the memory 313. As shown, the memory 313 of the control system 115 is configured to store power balancing control programming 330A, electrical data 111A-N, and no-load voltage values 112 for each of the DC-DC converters 109A-N. The control system 115 can also include sensors 315A-N coupled to the processor 312 to detect or monitor various system parameters, such as power, temperature, voltage, current, resistance, and/or impedance. For example, the sensors 315A-N can be coupled to the power bus 125.

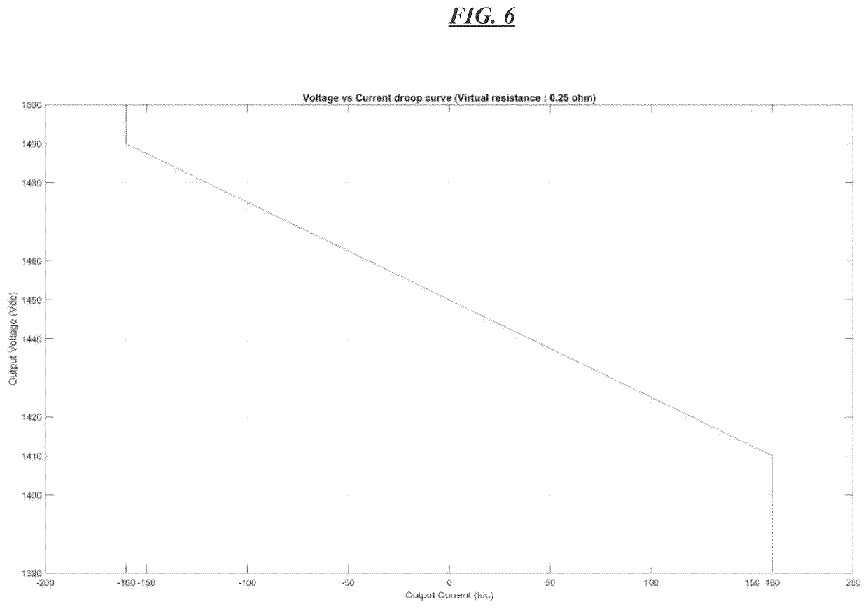

Control system 115 is configured to receive or store a “no-load” voltage value 112 (e.g., the potential difference or voltage across the terminals of the DC-DC converters before any load is connected) for each of the DC-DC converters 109A-N. The no-load voltage value 112 for each of the DC-DC converters 109A-N is based on a no-load voltage in a droop curve (FIG. 6). In particular, the no-load voltage value 112 for each of the DC-DC converters 109A-N is based on a no-load voltage defined as an output voltage value at zero output current in the droop curve (FIG. 6).

Control system 115 can calculate a required change in the no-load voltage value 112 for each of the DC-DC converters 109A-N, for example, based on electrical data 111A-N collected from each of the DC-DC converters 109A-N. The control system 115 can include one or more processors or computing devices, such as a closed loop proportional integral (PI) controller, for example, which can be configured to perform closed loop management of real and reactive power supplied to the electrical application 103.

Energy storage nodes 105A-N include a control subsystem 110, battery storage elements 106A-N, and a power conversion subsystem 107. Control subsystem 110 of the energy storage nodes 105A-N includes a network communication interface 351 configured for wired or wireless communication over the network 305. The control subsystem 110 further includes a memory 353, and a processor 352 coupled to the network communication interface 351 and the memory 353. As shown, the memory 353 of the control subsystem 110 is configured to store power balancing aware control programming 330B, electrical data 111A-N, and no-voltage values 112A-N for each of the DC-DC converters 109A-N.

The control subsystem 110 can further include environmental sensors 370A-N coupled to the processor 352. Environmental sensors 370A-N can measure humidity and temperature inside of an enclosure 400 of the energy storage nodes 105A-N.

The control subsystem 110 or the control system 115 can be configured to collect and record electrical data 111A-N from each of the plurality of DC-DC converters 109A-N. The electrical data 111A-N can be collected from readings from the data collection sensors 121A-N that monitor various electrical data 111A-N inside the DC-DC converters 109A-N, 119A-N or on both sides (inputs and outputs) of the DC-DC converters 109A-N, 119A-N, for example. Based on the collected electrical data 111A-N, the control subsystem 110 or the control system 115 can be configured to calculate an average power output for each of the plurality of DC-DC converters 109A-N. For example, the control subsystem 110 or the control system 115 can be configured to calculate an average power output for each of the plurality of DC-DC converters 109A-N as

$${P}_{avg} = \frac{{\sum }_{i = 1}^{i = n} {P}_{i}}{n}$$

where n is the number of parallelized DC-DC converters 109A-N and Pi are the power readings from each of the plurality of DC-DC converters 109A-N.

The control system 115 is configured to calculate the required change ΔVᵢ in the no-load voltage value 112 for each of the plurality of DC-DC converters 109A-N in a parallelized group to eliminate the power variation using a closed loop Proportional Integral (“PI”) controller:

$$Δ {V}_{i} = PI controller ( {P}_{avg} - {P}_{i} )$$

The control system 115 is configured to update the no-load voltage value 112 for each of the plurality of DC-DC converters 109A-N based on the calculated required change ΔVᵢ in the no-load voltage value 112 for each of the plurality of DC-DC converters 109A-N.

By updating the no-load voltage value 112 for each of the plurality of DC-DC converters 109A-N, the control system 115 provides a more nuanced and granular control over voltage passing through the converters 109A-N, which results in granular control over battery charging/discharging power. By balancing the power of each battery storage element 106A-N properly, the control system 115 enables higher battery utilization and reduced downtime across the plurality of energy storage nodes 105A-N.

In addition, the control system 115 manages the parallelized DC-DC converters 109A-N by a power balancing protocol, utilizing the droop curve of each DC-DC converter 109A-N to optimize the real-time, responsive voltage adjustments performed by the DC-DC converters 109A-N.

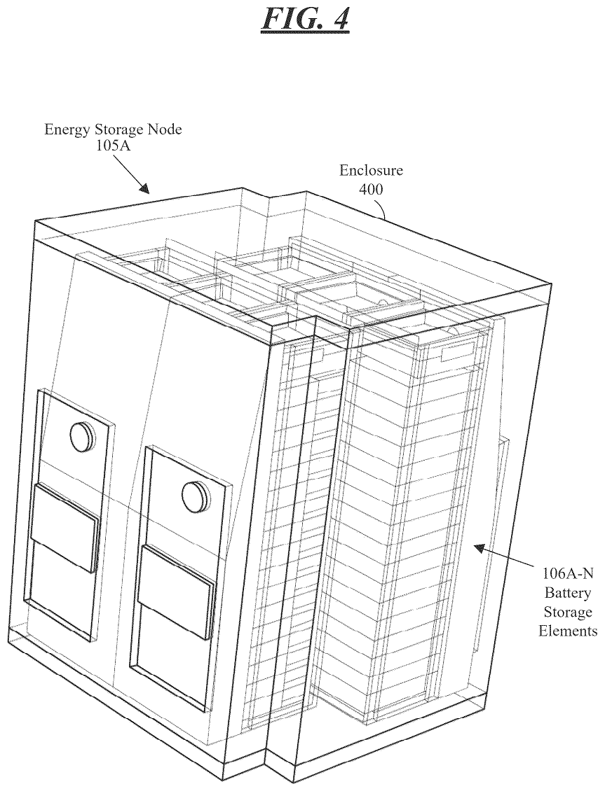

FIG. 4 is a cutaway view of the first energy storage node 105A of the plurality of energy storage nodes 105A-N and shows details of a plurality of battery storage elements 106A-N. As shown, the energy storage node 105A includes an enclosure 400, such as a physical housing to store a plurality of battery storage elements 106A-N. The battery storage elements 106A-N can be a collection of one or more batteries, such as a plurality of battery strings or battery banks, which are organized logically, physically, and electrically.

In the example of FIG. 4, the battery storage elements 106A-N can include battery racks (e.g., six are shown) that hold a respective stack of battery modules (e.g., seventeen are shown). The battery modules can include an array of prismatic, pouch, or cylindrical battery cells that are packaged together to increase voltage, amperage, or both. In some examples, battery modules may include an electric vehicle battery pack, e.g., a collection of lithium-ion battery cells that are packaged together.

Each of the plurality of DC-DC converters 109A-N can be connected to a separate rack of a corresponding one of the plurality of energy storage nodes 105A-N.

Each of the plurality of DC-DC converters 109A-N can be arranged in an enclosure 400 of a corresponding one of the plurality of energy storage nodes 105A-N.

The energy storage nodes 105A-N may resemble the features presented in the energy storage system described in International Application No. PCT/US2021/30551, filed on May 4, 2021, titled “Energy Storage System with Removable, Adjustable, and Lightweight Plenums,” the entirety of which is incorporated by reference herein.

FIG. 5 is a flowchart of the converter power balancing protocol 500. The converter power balancing protocol 500 can be implemented across an entire BESS 100 and all of the DC-DC converters 109A-N, or on a subset of components, such as a group of DC-DC converters 119A-E separately from another group of DC-DC converters 119F-J, as illustrated in FIG. 2, for example.

In an example, n number of DC-DC converters 109A-N are connected in parallel and run under a droop control mode. Each of the n number of DC-DC converters 109A-N has the same droop curve (see FIG. 6 for an example droop curve). However, due to variation in line impedance and sensor accuracy across the DC-DC converters 109A-N, every DC-DC converter 109A-N will not have equal power sharing with one another. The converter power balancing protocol 500 takes the actual output power from DC-DC converters 109A-N (or BMSs) outputted power, and adjusts the “no-load” voltage value in the respective droop curve of a particular DC-DC converter, e.g. 109A, in a group of DC-DC converters 109A-N such that equal power sharing among the DC-DC converters 109A-N can be achieved.

To facilitate this principle, the converter power balancing protocol 500 performs the following operations. In block 505, the converter power balancing protocol 500 records electrical data 111A-N including output voltage of the DC-DC converters 109A-N within the BESS 100. Other datapoints relevant to determining balance or SoC may be collected and recorded. These electrical data 111A-N are grouped by the groupings of parallelized DC-DC converters 109A-N, meaning that in the distributed model of FIG. 2, electrical data 111A-N would be grouped for DC-DC converters 119A-E, then DC-DC converters 119F-J, and further for DC-DC converters 119K-N, as each grouping of parallelized DC-DC converters 119A-N will be balanced on a separate basis.

In block 510, the converter power balancing protocol 500 selects the DC-DC converter 109A-N, 119A-N power output or the BMS power output from the electrical data 111A-N, and within each parallelized group assembles the power readings as
P₁, P₂, . . . , Pₙ
where n is the number of parallelized DC-DC converters or BMSs in a parallelized group.

Next, in block 515, the converter power balancing protocol 500 averages the power for the n number of DC-DC converters as

$${P}_{avg} = \frac{{\sum }_{i = 1}^{i = n} {P}_{i}}{n}$$

In block 520, the converter power balancing protocol 500 calculates the required change in the no-load voltage of each DC-DC converter in a parallelized group to eliminate the power variation using a closed loop Proportional Integral (“PI”) controller:

$$Δ {V}_{i} = PI controller ( {P}_{avg} - {P}_{i} )$$

Finally, in block 525, the converter power balancing protocol 500 updates the DC-DC converter no-load voltage

$${V}_{N - new}^{i} = {V}_{N}^{i} + Δ {V}_{i}$$

This process can be repeated on a scheduled or ad-hoc basis, and can occur infrequently, or hundreds of times per minute.

FIG. 6 is a graph of a voltage versus current droop curve. Output voltage value at zero output current is defined as “no-load” voltage in the droop curve.

In the examples above, the energy system 102, energy application 103, power conversion system 104, energy storage nodes 105A-N, control subsystem 110, control system 115, etc. can each include a processor. As used herein, a processor 312, 352 is a hardware circuit having elements structured and arranged to perform one or more processing functions, typically various data processing functions. Although discrete logic components could be used, the examples utilize components forming a programmable central processing unit (CPU). A processor 312, 352 for example includes or is part of one or more integrated circuit (IC) chips incorporating the electronic elements to perform the functions of the CPU. The processors 312, 352 for example, may be based on any known or available microprocessor architecture, such as a Reduced Instruction Set Computing (RISC) using an ARM architecture. Of course, other processor circuitry may be used to form the CPU or processor hardware in. The illustrated examples of the processors 312, 352 can include one microprocessor or a multi-processor architecture. A digital signal processor (DSP) or field-programmable gate array (FPGA) could be suitable replacements for the processors 312, 352, but may consume more power with added complexity.

The applicable processor 312, 352 executes programming or instructions to configure the energy system 102, energy application 103, power conversion system 104, energy storage nodes 105A-N, control subsystem 110, control system 115, etc. to perform various operations. For example, such operations may include various general operations (e.g., a clock function, recording and logging operational status and/or failure information) as well as various system-specific operations (e.g., daylighting and/or energy management) functions. Although a processor 312, 352 may be configured by use of hardwired logic, typical processors are general processing circuits configured by execution of programming, e.g., instructions and any associated setting data from the memories 313, 353 shown or from other included storage media and/or received from remote storage media.

In the examples above, the energy system 102, energy application 103, power conversion system 104, energy storage nodes 105A-N, control subsystem 110, control system 115, etc. each include a memory. The memory 313, 353 may include a flash memory (non-volatile or persistent storage), a read-only memory (ROM), and a random access memory (RAM) (volatile storage). The RAM serves as short term storage for instructions and data being handled by the processors 312, 352 e.g., as a working data processing memory. The flash memory typically provides longer term storage.

Of course, other storage devices or configurations may be added to or substituted for those in the example. Such other storage devices may be implemented using any type of storage medium having computer or processor readable instructions or programming stored therein and may include, for example, any or all of the tangible memory of the computers, processors or the like, or associated modules.

Hence, a machine-readable medium or a computer-readable medium may take many forms of tangible storage medium. Non-volatile storage media include, for example, optical or magnetic disks, such as any of the storage devices in any computer(s) or the like, such as may be used to implement the client device, media gateway, transcoder, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards, paper tape, any other physical storage medium with patterns of holes, a RAM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

According to exemplary embodiments of the present disclosure the one or more processors and control circuits can include one or more of any known general purpose processor or integrated circuit such as a central processing unit (CPU), microprocessor, field programmable gate array (FPGA), Application Specific Integrated Circuit (ASIC), Digital Signal Processor (DSP), or other suitable programmable processing or computing device or circuit as desired that is specially programmed to perform operations for achieving the results of the exemplar embodiments described herein. The processor(s) can be configured to include and perform features of the exemplary embodiments of the present disclosure, such as the battery condition aware control protocol 400 and the power balancing control programming 330A-B. The features can be performed through program code encoded or recorded on the processor(s), or stored in a non-volatile memory device, such as Read-Only Memory (ROM), erasable programmable read-only memory (EPROM), or other suitable memory device or circuit as desired. Accordingly, such computer programs can represent controllers of the computing device.

In another exemplary embodiment, the program code, such as the battery condition aware control protocol 400 and the power balancing control programming 330A-B, can be provided in a computer program product having a non-transitory computer readable medium, such as Magnetic Storage Media (e.g. hard disks, floppy discs, or magnetic tape), optical media (e.g., any type of compact disc (CD), or any type of digital video disc (DVD), or other compatible non-volatile memory device as desired) and downloaded to the processor(s) for execution as desired, when the non-transitory computer readable medium is placed in communicable contact with the processor(s).

The one or more processors 312, 352 can be included in a computing system that is configured with components such as memory, a hard drive, an input/output (I/O) interface, a communication interface, a display and any other suitable component as desired. The exemplary computing device can also include a communications interface. The communications interface can be configured to allow software and data to be transferred between the computing device and external devices. Exemplary communications interfaces can include a modem, a network interface (e.g., an Ethernet card), a communications port, a PCMCIA slot and card, or any other suitable network communication interface as desired. Software and data transferred via the communications interface can be in the form of signals, which can be electronic, electromagnetic, optical, or other signals as will be apparent to persons having skill in the relevant art. The signals can travel via a communications path, which can be configured to carry the signals and can be implemented using wire, cable, fiber optics, a phone line, a cellular phone link, a radio frequency link, or any other suitable communication link as desired.

Where the present disclosure is implemented using programming or software, including the battery condition aware control protocol 400 and the power balancing control programming 330A-B, the programming or software can be stored in a computer program product or non-transitory computer readable medium and loaded into the computing device using a removable storage drive or communications interface. In an exemplary embodiment, any computing device, such as control system 115 and control subsystem 110, disclosed herein can also include a display interface that outputs display signals to a display unit, e.g., LCD screen, plasma screen, LED screen, DLP screen, CRT screen, or any other suitable graphical interface as desired.

It will be understood that the terms and expressions used herein have the ordinary meaning as is accorded to such terms and expressions with respect to their corresponding respective areas of inquiry and study except where specific meanings have otherwise been set forth herein. Relational terms such as first and second, or evident and alternative, and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without further constraints, preclude the existence of additional identical elements in the process, method, article, or apparatus that comprises the element.

Unless otherwise stated, any and all measurements, values, ratings, positions, magnitudes, sizes, angles, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as +5% or as much as +10% from the stated amount. The terms “approximately” and “substantially” mean that the parameter value or the like varies up to +10% from the stated amount or position.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present concepts.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

What is claimed is:

1. An energy storage system, comprising:
a plurality of energy storage nodes, wherein each of the plurality of energy storage nodes includes a battery storage element;
a plurality of DC-DC converters connected in parallel, each of said plurality of DC-DC converters being connected to a corresponding one of the energy storage nodes; and
a controller coupled to the plurality of DC-DC converters and configured to execute a power balancing protocol including:
collecting and recording electrical data from each of the plurality of DC-DC converters,
calculating an average power output for the plurality of DC-DC converters based on the electrical data,
calculating a required change in a no-load voltage value for each of the plurality of DC-DC converters, and
updating the no-load voltage value for each of the plurality of DC-DC converters based on the calculated required change in the no-load voltage value for each of the plurality of DC-DC converters.

2. The energy storage system of claim 1, wherein the required change in the no-load voltage value for each of the plurality of DC-DC converters is calculated to eliminate a power variation by using a closed loop proportional integral (PI) controller.

3. The energy storage system of claim 1, wherein the no-load voltage value for each of the plurality of DC-DC converters is based on a no-load voltage in a droop curve.

4. The energy storage system of claim 3, wherein the no-load voltage value for each of the plurality of DC-DC converters is based on a no-load voltage defined as an output voltage value at zero output current in the droop curve.

5. The energy storage system of claim 1, further comprising power conversion systems configured to convert direct current into alternating current, wherein each of the plurality of DC-DC converters is connected between a corresponding one of the plurality of energy storage nodes and a corresponding one of the power conversion systems via a DC bus.

6. The energy storage system of claim 5, wherein the power balancing protocol further includes grouping the electrical data by groups of the plurality of DC-DC converters connected to the same power conversion system, and executing the power balancing protocol separately for each group of the plurality of DC-DC converters.

7. The energy storage system of claim 6, wherein the controller is configured to execute the power balancing protocol separately for all groups of the plurality of DC-DC converters.

8. The energy storage system of claim 1, wherein each of the plurality of DC-DC converters is connected to a separate rack of a corresponding one of the plurality of energy storage nodes.

9. The energy storage system of claim 1, wherein each of the plurality of DC-DC converters is arranged in an enclosure of a corresponding one of the plurality of energy storage nodes.

10. The energy storage system of claim 1, further comprising a plurality of data collection sensors configured to collect operational data.

11. The energy storage system of claim 10, wherein the operational data comprises the electrical data.

12. The energy storage system of claim 11, wherein the electrical data comprises at least one of current and voltage or power output of the power conversion system.

13. A method, comprising:
connecting a plurality of parallel DC-DC converters to a plurality of energy storage nodes;
collecting and recording electrical data from each of the plurality of parallel DC-DC converters;
calculating an average power output for the plurality of parallel DC-DC converters based on the electrical data;
calculating a required change in a no-load voltage value for each of the plurality of parallel DC-DC converters; and
updating the no-load voltage value for each of the plurality of parallel DC-DC converters based on the calculated required change in the no-load voltage value for each of the plurality of parallel DC-DC converters.

14. The method of claim 13, wherein the required change in the no-load voltage value for each of the plurality of DC-DC converters is calculated to eliminate a power variation by using a closed loop proportional integral (PI) controller.

15. The method of claim 13, further comprising connecting power conversion systems configured to convert direct current into alternating current, wherein each of the plurality of DC-DC converters is connected between a corresponding one of the plurality of energy storage nodes and a corresponding one of the power conversion systems via a DC bus.

16. The method of claim 15, further comprising grouping the electrical data by groups of the plurality of parallel DC-DC converters connected to the same power conversion system.

17. The method of claim 16, further comprising calculating the average power output and the required change in the no-load voltage value separately for each group of the plurality of parallel DC-DC converters.

18. The method of claim 17, further comprising updating the no-load voltage value separately for each group of the plurality of parallel DC-DC converters based on the calculated required change in the no-load voltage value for each group of the plurality of parallel DC-DC converters.

19. The method of claim 13, further comprising operating the plurality of parallel DC-DC converters in a droop control mode.

20. The method of claim 13, wherein the no-load voltage value for each of the plurality of DC-DC converters is based on a no-load voltage in a droop curve.
